(19) United States
(12) Patent Application Publication
(10) Pub. No.: US 2013/0119545 A1
(43) Pub. Date: May 16, 2013

(54) SEMICONDUCTOR DEVICE AND METHOD FOR FORMING THE SAME

(71) Applicant: Un Hee LEE, Icheon-si (KR)

(72) Inventor: Un Hee LEE, Icheon-si (KR)

(73) Assignee: Hynix Semiconductor Inc., Icheon-si (KR)

(21) Appl. No.: 13/347,570

(22) Filed: Jan. 10, 2012

(30) Foreign Application Priority Data
Nov. 14, 2011 (KR) 10-2011-0118462

(51) Int. Cl. H01L 23/532; H01L 21/768

(52) U.S. Cl. 257/751; 438/653; 257/E23.155; 257/E21.584

(57) ABSTRACT

A semiconductor device and a method for forming the same are disclosed, which can protect a polysilicon layer of a bit line contact plug even when a critical dimension (CD) of the bit line is reduced by a fabrication change, thereby preventing defective resistivity caused by a damaged bit line contact plug from being generated. The semiconductor device includes one or more interlayer insulation film patterns formed over a semiconductor substrate, a bit line contact plug formed over the semiconductor substrate between the interlayer insulation films, and located below a top part of the interlayer insulation film pattern, and a bit line formed over the bit line contact plug.

### CROSS-REFERENCE TO RELATED APPLICATION

The priority of Korean patent application No. 10-2011-0118462 filed on 14 Nov. 2011, the disclosure of which is hereby incorporated in its entirety by reference, is claimed.

### BACKGROUND OF THE INVENTION

The present invention relate to a semiconductor device, and more particularly to a semiconductor device including a Global Bit Line (GBL).

In recent times, technologies of 40 nm or less have been applied to semiconductor devices so that a Global Bit Line (GBL) process has been proposed. However, if misalignment between a bit line contact and a bit line occurs, the GBL process may generate a poor self-aligned contact (SAC) between a bit line contact and a storage node contact. If it is assumed that a thick bit line spacer is formed to solve the above-mentioned problem, a Not-Open phenomenon can occur in the storage node contact. In addition, if the bit line contact spacer is formed thick, resistance of the bit line contact is increased. In order to prevent the increasing resistance of the bit line contact, an inner GBL process has been proposed. However, in the case of the inner GBL process, a bit line contact plug is coupled to an active region between buried gates, and the bit line is deposited to be coupled to an upper part of the bit line contact plug. In addition, the storage node contact plug is located at both sides of the bit line and is coupled to the active region. However, since the bit line contact plug is formed close to the storage node contact plug, the bit line contact plug is coupled to the storage node contact plug located at both sides of the bit line, resulting in a short-circuit between the bit line contact plug and the storage node contact plug.

In order to prevent a short-circuit between the bit line contact plug and the storage node contact plug, in the case where the bit line is formed to have a large width or a spacer formed at sidewalls of the bit line is formed thick, a coupling region between the active region and the storage node contact plug is reduced in size, resulting in increased resistance.

FIG. 1 is a cross-sectional view illustrating a semiconductor device and its problems according to the related art.

FIG. 1(i) shows a semiconductor device according to the related art. A device isolation film 13 defining an active region 14 is formed over a semiconductor substrate 10, and an interlayer insulation film 15 defining a bit line contact hole is formed over the semiconductor substrate. In addition, a polysilicon layer is buried in the bit line contact hole, such that the bit line contact plug 20 is formed. A bit line 45 is formed to connect to the bit line contact plug 20. The bit line 45 may be formed of a laminate structure of a barrier metal layer 25, a bit line conductive layer 35, and a hard mask layer 40. In this case, critical dimension (CD) of an upper part of the bit line contact plug 20 may be identical to that of a lower part of the bit line 45.

However, there may occur a specific area in which the CD of the lower part of the bit line 45 is less than that of the upper part of the bit line contact plug 20. In this case, as shown in the part (A) of FIG. 1(ii), a defective part may occur in which a polysilicon layer of the bit line contact plug 20 is damaged. The polysilicon layer has a high etch selection ratio, such that the etched sections are increased rapidly in size even when the polysilicon layer is slightly exposed.

As described above, the conventional semiconductor device does not include a barrier layer capable of protecting the bit line contact plug 20 if the CD of the bit line 45 is reduced, such that the top part of the bit line contact plug 20 exposed by the bit line 45 is etched during the etching of the bit line 45, resulting in the occurrence of defective or poor resistivity.

### BRIEF SUMMARY OF THE INVENTION

Various embodiments of the present invention are directed to providing a semiconductor device and a method for manufacturing the same that substantially obviate one or more problems due to limitations and disadvantages of the related art.

An embodiment of the present invention relates to a semiconductor device and a method for manufacturing the same, which can protect a polysilicon layer of a bit line contact plug even when a critical dimension (CD) of the bit line is reduced by a fabrication change, so as to prevent defective resistivity caused by a damaged bit line contact plug from being generated.

In accordance with an aspect of the present invention, a semiconductor device includes one or more interlayer insulation film patterns formed over a semiconductor substrate; a bit line contact plug formed over the semiconductor substrate between the interlayer insulation films, and located below a top part of the interlayer insulation film pattern; and a bit line formed over the bit line contact plug.

The bit line contact plug may include polysilicon. The interlayer insulation film pattern may include a nitride film.

The bit line may be formed of a laminate structure of a barrier metal layer, a bit line conductive layer, and a hard mask layer. The barrier metal layer may be formed not only over the bit line contact plug but also over a lateral surface of the interlayer insulation film. The barrier metal layer may include any one of a titanium film, a titanium nitride film, a tungsten nitride film, a tungsten silicon nitride film, and a combination thereof.

The bit line conductive layer may include tungsten. The semiconductor device may further include a spacer insulation film formed over the entire surface of the interlayer insulation film including the bit line.

A critical dimension (CD) (or a width) of the bit line may be identical to that of the top part of the bit line contact plug. If a critical dimension (CD) of the bit line is smaller than that of the top part of the bit line contact plug, the top part of the bit line contact plug is covered with the barrier metal layer or the bit line conductive layer.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a cross-sectional view illustrating a semiconductor device according to the related art.

FIG. 2 is a cross-sectional view illustrating a semiconductor device according to an embodiment of the present invention.

FIGS. 3A to 3E are cross-sectional views illustrating a method for manufacturing a semiconductor device according to embodiments of the present invention.

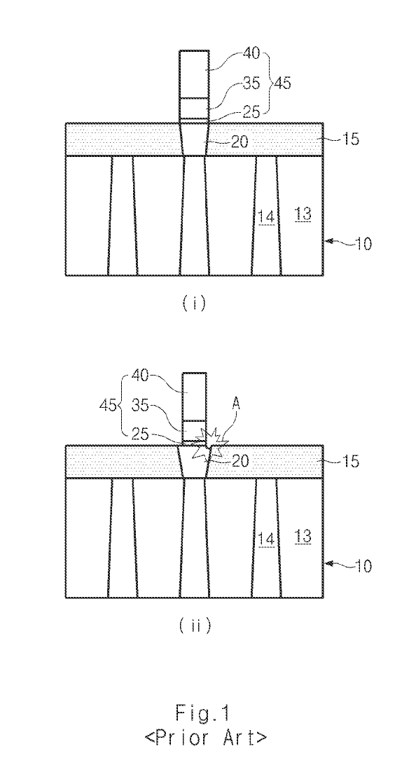

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts. A semiconductor device and a method for manufacturing the same according to embodiments of the present invention will hereinafter be described with reference to the accompanying drawings.

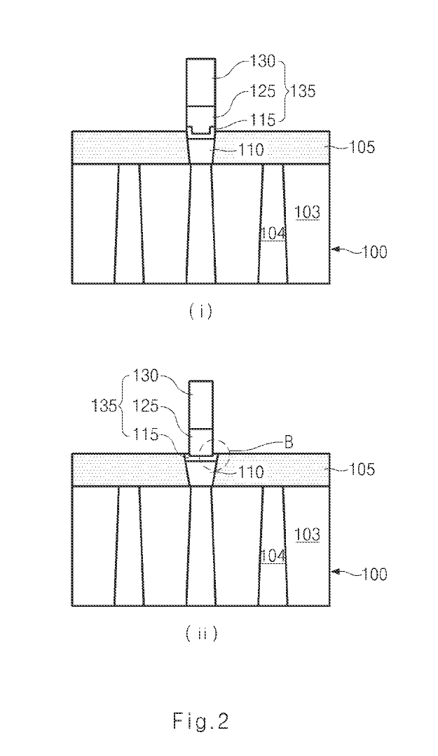

FIG. 2 is a cross-sectional view illustrating a semiconductor device according to an embodiment of the present invention.

Referring to FIG. 2(i), a buried gate structure (not shown) is contained in a semiconductor substrate 100 including a device isolation film 103 defining an active region 104. An interlayer insulation film 105 defining a bit line contact hole is formed over the surface of the semiconductor substrate 100 including a buried gate structure (not shown). The interlayer insulation film 105 (also referred to as “interlayer insulation film pattern”) may include a nitride film. A bit line contact plug 110 is formed by burying a polysilicon layer in the bit line contact hole. In an embodiment, the height of the top part of the bit line contact plug 110 may be located below the top part of the interlayer insulation film 105. That is, the bit line contact plug has a top surface that is provided at a lower level than a top surface of the interlayer insulation film 105.

In addition, a bit line 135 coupled to the bit line contact plug 110 is formed over the bit line contact plug 110. Since the height of the bit line contact plug 110 is less than that of the interlayer insulation film 105, the bit line 135 formed over the bit line contact plug 110 is recessed by the height of the bit line contact plug 110. The bit line 135 may be formed of a laminate structure of the barrier metal layer 115, the bit line conductive layer 125, and the hard mask layer 130. The barrier metal layer 115 located at the lower part of the bit line 135 is formed along the top part of the bit line contact plug 110 and a lateral surface of the interlayer insulation film 105 exposed by the bit line contact plug 110. That is, the barrier metal layer 115 includes a horizontal portion and a vertical portion, where the horizontal portion is provided over the top surface of the bit line contact plug and the vertical portion is provided over a sidewall of the bit line contact hole of the interlayer insulation film and extends above the horizontal portion. The barrier metal layer 115 may include any one of a titanium (Ti) film, a titanium nitride (TiN) film, a tungsten nitride (TaN) film, a tungsten silicon nitride film, and a combination thereof. The bit line conductive layer 125 may include tungsten having superior electrical conductivity, and the hard mask layer 130 may include a nitride film.

As can be seen from the recessed bit line 135 located below the top part of the interlayer insulation film 105, although the CD of the bit line 135 is reduced as shown in FIG. 2(ii), the semiconductor device according to the present embodiment can prevent the bit line contact plug 110 from being exposed/damaged by the barrier metal layer 115 or the bit line conductive layer 125 (See the part ‘B’ of FIG. 2(ii)).

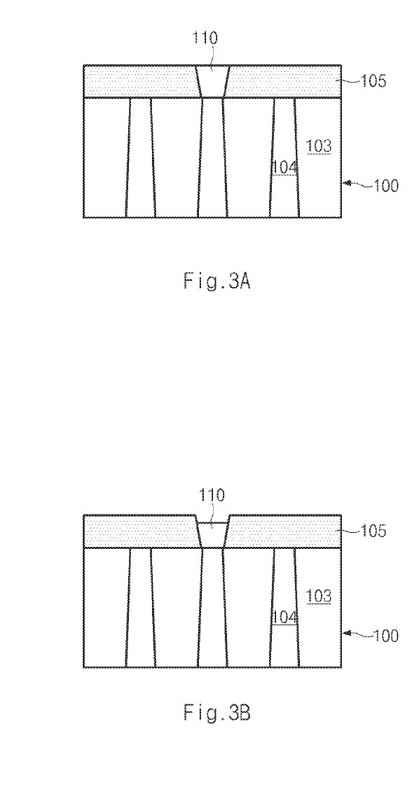

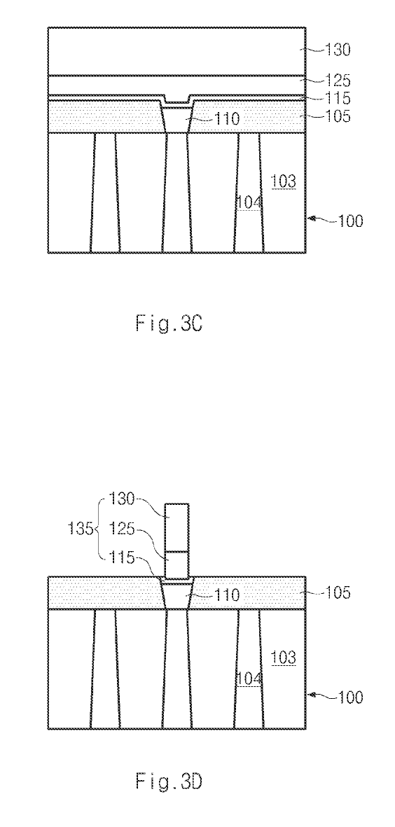

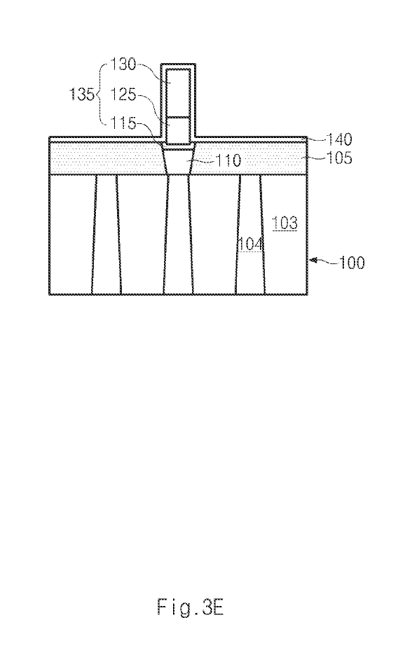

FIGS. 3A to 3E are cross-sectional views illustrating a method for manufacturing a semiconductor device according to embodiments of the present invention.

Referring to FIG. 3A, a trench for a device isolation film defining an active region 104 is formed by etching a semiconductor substrate 100. A liner oxide film (not shown) and a liner nitride film (not shown) are formed at an inner wall of the trench. In this case, the liner oxide film (not shown) may increase a deposition rate with a liner nitride film to be formed in a subsequent process, and the liner nitride film (not shown) may absorb or buffer stress caused by a difference in thermal expansive coefficient between the liner nitride film and an insulation film for device isolation.

Thereafter, the insulation film for device isolation is formed over the semiconductor substrate 100 including the trench, and a planarization etching process is performed on the resultant insulation film, so that a device isolation film 103 is formed. In this case, the device isolation film 103 may include any one of a Spin On Dielectric (SOD) film, a High Density Plasma (HDP) film, and a combination thereof. Although not shown in FIG. 3A, after the formation of the device isolation film 103, the device isolation film 103 and the active region 104 may be etched to form a recess, and a buried gate may be formed to be buried in the recess. However, a process for forming a buried gate and a detailed description of the buried gate will herein be omitted for the convenience of description and better understanding of the present invention.

Thereafter, an interlayer insulation film 105 is formed over the semiconductor substrate 100, and a mask pattern (not shown) exposing a region reserved for a bit line contact hole is formed over the interlayer insulation film 105. Preferably, the interlayer insulation film 105 may include a nitride film. The interlayer insulation film 105 is etched using the mask pattern (not shown) as an etch mask, so that a bit line contact hole is formed. Thereafter, after removing the mask pattern (not shown), a polysilicon layer is formed over the entirety of the interlayer insulation film 105 including the bit line contact hole, and a planarization process is performed until the interlayer insulation film 105 is exposed, so that a bit line contact plug 110 is formed.

Referring to FIG. 3B, the top part of the bit line contact plug 110 is recessed by an etchback process. As a result, the top part of the bit line contact plug 110 is located below the top part of the interlayer insulation film 105.

Referring to FIG. 3C, a barrier metal layer 115 is deposited along the surface of the interlayer insulation film 105 including the recessed bit line contact plug 110. Thereafter, a planarized bit line conductive layer 125 is formed over the barrier metal layer 115, and a hard mask layer 130 is formed over the bit line conductive layer 125. The barrier metal layer 115 may include a titanium (Ti) film, a titanium nitride (TiN) film, a tungsten nitride (TaN) film, a tungsten silicon nitride film, and a combination thereof. The bit line conductive layer 125 may be formed of a material including tungsten having superior electrical conductivity. In addition, the hard mask layer 130 may be formed of a material including a nitride film.

Referring to FIG. 3D, after a mask pattern (not shown) defining a bit line is formed over the hard mask layer 130, the hard mask layer 130, the bit line conductive layer 125 and the barrier metal layer 115 are etched using the mask pattern (not shown) as an etch mask, such that the bit line 135 is formed. In this case, the etching process for forming the bit line 135 may be performed until the interlayer insulation film 105 located at both sides of the bit line contact plug 110 is exposed, and may also be performed with the same CD as that of the bit line contact plug 110.

On the other hand, if the CD of the bit line 135 is smaller than that of the bit line contact plug 110 as shown in FIG. 3D, the barrier metal layer 115 or the bit line conductive layer 12 formed over the bit line contact plug 110 is exposed. However, the bit line contact plug 110 is still covered by the barrier metal layer 115, such that the polysilicon layer of the bit line contact plug 110 is prevented from being damaged.

Referring to FIG. 3E, a spacer insulation film 140 is formed over the entire surface of the semiconductor substrate 100 including the bit line 135 and the bit line contact plug 110. In this case, the spacer insulation film 140 may be deposited using a Chemical Vapor Deposition (CVD) process, and may be formed of a material including a nitride film. The spacer insulation film 140 may prevent a bridge between the storage node contact plug and the bit line contact plug 110 from occurring in a subsequent process.

As is apparent from the above description, according to the recessed bit line 135 located below the top part of the interlayer insulation film 105, although the CD of the bit line 135 is reduced as shown in FIG. 3D, the semiconductor device according to the present embodiment can prevent the bit line contact plug 110 from being exposed/damaged by the barrier metal layer 115 or bit line conductive layer 125 formed over the bit line contact plug 110.

In an embodiment, a method for forming a semiconductor device includes providing a substrate having an interlayer insulation film over an active region and a device isolation film of the substrate. The interlayer insulation film defines a bit line contact hole exposing the active region. A layer of material is formed over the interlayer insulation film and into the bit line contact hole. The layer of material is removed until the layer of material provided within the bit line contact hole is substantially flushed to a top surface of the interlayer insulation film. A top portion of the layer of material provided within the bit line contact hole is etched so that a resulting top surface of the layer of material is at a lower height than the top surface of the interlayer insulation film. A bit line is formed over the top surface of the layer of material, the bit line partly extending into the bit line contact hole. The layer of material provided within the bit line contact hole defines a bit line contact plug.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A semiconductor device comprising:
a substrate having an active region and a device isolation film;
an interlayer insulation film formed over the substrate and defining a bit line contact hole exposing the active region;
a bit line contact plug provided within the bit line contact hole defined by the interlayer insulation film, the bit line contact plug having a top surface that is provided at a lower level than a top surface of the interlayer insulation film pattern; and
a bit line formed over the bit line contact plug and electrically connected to the bit line contact plug.

2. The semiconductor device according to claim 1, wherein the bit line contact plug includes polysilicon.

3. The semiconductor device according to claim 1, wherein the interlayer insulation film includes a nitride film.

4. The semiconductor device according to claim 1, wherein the bit line is formed of a laminate structure including a barrier metal layer, a bit line conductive layer, and a hard mask layer.

5. The semiconductor device according to claim 4, wherein the barrier metal layer includes a horizontal portion and a vertical portion, the horizontal portion being provided over the top surface of the bit line contact plug, the vertical portion being provided over a sidewall of the bit line contact hole of the interlayer insulation film and extending above the horizontal portion.

6. The semiconductor device according to claim 4, wherein the barrier metal layer includes any one of a titanium film, a titanium nitride film, a tungsten nitride film, a tungsten silicon nitride film, and a combination thereof.

7. The semiconductor device according to claim 4, wherein the bit line conductive layer includes tungsten.

8. The semiconductor device according to claim 1, further comprising:
a spacer insulation film formed over the interlayer insulation film and the bit line, the spacer insulation film conforming to a shape of the bit line.

9. The semiconductor device according to claim 1, wherein a width of the bit line is substantially the same as a width of a top portion of the bit line contact plug.

10. The semiconductor device according to claim 1, wherein a width of the bit line is smaller than a width of a top portion of the bit line contact plug, the bit line including a barrier metal layer and a bit line conductive layer,
wherein the barrier metal layer is provided over the bit line contact plug and within the bit line contact hole, and the bit line conductive layer is provided over the barrier metal layer and partly within the bit line contact hole.

11. A method for forming a semiconductor device, the method comprising:
providing a substrate having an interlayer insulation film over an active region and a device isolation film of the substrate, the interlayer insulation film defining a bit line contact hole exposing the active region;
forming a layer of material over the interlayer insulation film and into the bit line contact hole;
removing the layer of material until the layer of material provided within the bit line contact hole is substantially flushed to a top surface of the interlayer insulation film;
etching a top portion of the layer of material provided within the bit line contact hole so that a resulting top surface of the layer of material is at a lower height than the top surface of the interlayer insulation film;
forming a bit line over the top surface of the layer of material, the bit line partly extending into the bit line contact hole,
wherein the layer of material provided within the bit line contact hole defines a bit line contact plug.
